(19) United States
(12) Patent Application Publication
(10) Pub. No.: US 2004/0132295 A1
(43) Pub. Date: Jul. 8, 2004

(54) Method and device to remove unwanted material from the edge region of a workpiece

(76) Inventors: Bulent M. Basol, Manhattan Beach, CA (US); Homayoun Talieh, San Jose, CA (US); Boris I. Govzman, Sunnyvale, CA (US); Boris Fuksshimov, San Jose, CA (US)

Correspondence Address: NuTool, Inc., Legal Department, 1655 McCandless Drive, Milpitas, CA, 95035, US

(21) Appl. No.: 10/698,875

(22) Filed: Oct. 31, 2003

Related U.S. Application Data
(60) Provisional application No. 60/423,285, filed on Nov. 1, 2002.
(60) Provisional application No. 60/429,616, filed on Nov. 27, 2002.

(51) Int. Cl. H01L 21/302; H01L 21/461

(52) U.S. Cl. 438/689; 438/692

(57) ABSTRACT

A method of removing edge material from a workpiece includes the steps of supplying an etch solution to create an etchant bead at an opening of an edge removal device, contacting the etchant bead with an edge region of the workpiece, and rotating the workpiece to remove the edge material from the workpiece. In one aspect, the step of supplying the etch solution includes the step of maintaining the etchant bead at the opening of the edge removal device. In another aspect, the edge removal device includes a cavity having the opening and the step of contacting the etchant bead includes inserting the edge region of the workpiece into the cavity.

### RELATED APPLICATIONS

This application claims priority based on U.S. Provisional Application Numbers 60/423,285 filed Nov. 1, 2002 (NT-283-P) and 60/429,616 filed Nov. 27, 2002 (NT-286-P), all incorporated herein by reference.

### FIELD

The present invention generally relates to semiconductor processing technologies and, more particularly, to a system and process that removes an excess material layer from the edge region of a workpiece.

### BACKGROUND

In the semiconductor industry, various processes can be used to deposit and etch materials on the wafers. Deposition techniques include processes such as electrochemical deposition (ECD) and electro chemical mechanical deposition (ECMD). In both processes, a conductor is deposited on a semiconductor wafer or a work piece by having electrical current carried through an electrolyte that comes into contact with the surface of the wafer (cathode). A detailed description of the ECMD method and apparatus can be found in U.S. Pat. No. 6,176,992 entitled “Method and Apparatus For Electro Chemical Mechanical Deposition”, commonly owned by the assignee of the present invention.

Regardless of which process is used, the work piece is next transferred to a cleaning and drying station after the deposition step. During the cleaning steps, various residues generated by the deposition process are rinsed off the wafer, and subsequently the wafer is dried by spinning and if necessary blowing nitrogen on its surface. In one design, the ECD or ECMD chamber and the rinse chamber can be stacked vertically in a vertical process chambers arrangement. In this arrangement, the plating process can be performed in a lower chamber, and the cleaning and drying can be carried out in an upper chamber after isolating the upper chamber from the lower chamber. One such vertical chamber is disclosed in U.S. Pat. No. 6,352,623 entitled “Vertically Configured Chamber Used for Multiple Processes”, commonly owned by the assignee of the present invention.

Conventionally, after the plating process is performed to deposit the conductive material, the work piece may be polished mechanically and chemically, e.g., chemical mechanical polishing (CMP), so as to remove the overburden conductive material from the front face of the work piece. As is known, the material removal can also be carried out using chemical etching or electrochemical etching or polishing. In electrochemical etching, the conductive material on the wafer surface is made anodic (positive) with respect to an electrode in a suitable process solution. A pad may or may not be touching the surface of the conductive material during this material removal process.

Copper is a preferred conductive material that can be deposited by ECD and ECMD processes. Therefore it will be used as an example, although the present invention can be used for any other material deposited on a workpiece. These other materials include but are not limited to conductors, dielectric layers and photoresist materials.

Referring back to the example of copper deposition by electroplating, during process copper may be deposited on the edges and sides (also called bevel) of the wafer where no ICs or circuits are located. Such remaining copper, which is often referred to as the edge copper, may migrate to neighboring active regions from the sides and edges of the wafer. Further, copper from a wafer edge may contaminate the wafer transport system, and so be passed on to contaminate other wafers. For this reason, it is important to remove the copper from the edges and the bevel of the wafer following each copper plating step before further processing the wafer. For example, after wafer plating, edge copper may first be removed. Wafer may then be annealed and then processed by CMP to remove copper and barrier layers. If an electropolishing approach is used for excess copper removal, then after copper deposition electropolishing may be performed by making electrical contacts to the edge region of the wafer. Then after this step, the edge copper can be removed. In electropolishing techniques using electrical contacts to the surface of the wafer away from the edge region, the edge copper would not be needed to establish electrical contact with a power supply during electropolishing. Therefore, in such cases the edge copper can be removed before the electropolishing process. No matter what approach is taken, the edge copper, which includes the backside edge of the wafer as well as its bevel and the front side edge, needs to be removed at some step of the overall wafer processing flow.

One method of removing the edge copper involves directing at least one well regulated stream of an etchant solution at the edge of the wafer while the wafer is rotated. Nozzles with very small orifices are generally used for this purpose and the stream of the etching solution is sent onto the wafer edge from a distance, e.g. 5-10 mm. Etching solutions are typically acidic and oxidizing solutions, such as aqueous sulfuric acid and hydrogen peroxide solutions, which oxidize copper and remove it at a high rate. Generally, the etching rate may vary depending on the process time, temperature and the chemical composition of the etching solution. The etchant is applied in the form of a well regulated stream through at least one nozzle. The angle of the etchant stream with respect to the wafer surface, its velocity and flow rate are among variables that need to be adjusted to achieve desirable results from the copper removal process. Otherwise, splashing of the etchant onto the wafer surface or fine mist generated by the etchant stream hitting the rotating wafer edge at high velocity may give rise etching or corrosion outside the edge area and thus cause defects on the wafer. The flow rate of the etchant stream and the rpm of the wafer need to be carefully adjusted so that the bevel or the side of the wafer can be cleaned and be free of copper. For good bevel clean, there should be good wrap-around of the bevel by the etchant. As the wafer is rotated, centrifugal force tries to push the etchant away from the bevel, whereas the surface tension tries to wrap it around the bevel. Fine adjustment and balancing of these parameters are needed for good results. For wafers with relatively thick unwanted copper at the edge region including the bevel (such as wafers that are plated in apparatus causing plating at the edge region) it is especially challenging to adjust all the process parameters to have effective edge copper removal. For example, if the rpm of the wafer is reduced to improve the wrap-around of the etchant and therefore increase the removal rate at the bevel region, one may loose the edge definition of the copper-free region on the surface of the wafer, i.e. wrapped-around etchant may move to the face of the wafer due to surface tension and then move in towards the center of the wafer beyond the edge region it is intended to remove. This is because, at low rpm centrifugal force is lower and may not effectively counter the surface tension of the etchant on the wafer surface. If rpm is increased to improve the edge definition of the etched edge copper top portion, then more etchant needs to be directed onto the edge to be able to effectively etch the thick edge copper. This cuts down the throughput, increases etchant usage and chemical waste and increases cost.

To address some of these issues a new electrochemical edge and bevel cleaning process and system has been disclosed in U.S. patent application Ser. No. 10/032,318, filed Dec. 21, 2001), commonly owned by the assignee of the present invention.

During other process steps other materials, conductor or insulator, may also be deposited on the wafer surface in the form of layers. Unwanted portions of these material layers may also be removed from the edge portion at some point in the process. One such requirement arises during the steps of photoresist deposition. Photoresist is typically deposited on the wafer surface in the form of a thin layer using a spin technique. Although the photoresist layer is substantially planar, it forms a “bead” at the edge of the wafer. After further processing, the portion of the photoresist at the edge of the wafer needs to be removed to eliminate this beaded section so that flatness of the workpiece may be attained. This process is often called “edge bead removal” and it typically involves directing a stream of photoresist removal solution at the edge of the wafer. Challenges of such approach are similar to those discussed in relation with the edge copper removal using a directed stream of etchant.

To this end, there is a need for improved methods of removing unwanted material layers in an efficient and effective manner from the edge regions of workpieces.

### SUMMARY

The invention is directed to a method and apparatus for removing a deposited layer from an edge region of a workpiece. According to one embodiment of the invention, an edge removal device is supplied with etchant solution that forms an etchant bead at an opening of the edge removal device. A workpiece contacts the etchant bead at the opening of the edge removal device. The etchant bead in contact with an edge region of the workpiece removes edge material from the workpiece. The workpiece is rotated to produce edge material removal around the circumference of the workpiece that come in contact with the etchant bead. A constant supply of etchant solution is provided to the edge removal device to maintain an adequate etchant bead.

These and other features, aspects and advantages of the present invention will become better understood with reference to the following drawings, description and claims.

### BRIEF DESCRIPTION OF THE DRAWINGS

The above and other objectives, features, and advantages of the present invention are further described in the detailed description which follows, with reference to the drawings by way of non-limiting exemplary embodiments of the present invention, wherein like reference numerals represent similar parts of the present invention throughout several views and wherein:

FIG. 1 illustrates a top plane view of a plated workpiece;

FIG. 2 illustrates an exemplary cross-section of a peripheral edge of a wafer after deposition of material;

FIG. 3A illustrates a cross-section of an edge removal device and a partial view of a workpiece according to an embodiment of the present invention;

FIG. 3B illustrates a top view of an edge removal device and a partial view of a workpiece according to an embodiment of the present invention;

FIG. 3C illustrates placement of an edge material removal device in a processing system according to an embodiment of the present invention;

FIG. 3D illustrates an alternative placement of an edge material device in a processing system according to an embodiment of the present invention;

FIG. 4A illustrates an edge portion of a workpiece in contact with etchant contained in an edge removal device according to an embodiment of the present invention;

FIG. 4B illustrates an edge portion of a workpiece in contact with an edge removal device according to an alternative embodiment of the edge removal device;

FIG. 4C illustrates an alternative embodiment of an edge removal device;

FIGS. 4D-4E illustrate an alternative embodiment of an edge removal device;

FIGS. 4Da-4Db illustrate alternative embodiments of V-shaped openings;

FIG. 5 illustrates an exemplary workpiece with the edge portion removed;

FIG. 6 illustrates an open cavity embodiment of an edge removal device according to the present invention; and

FIG. 7 illustrates an embodiment of an edge removal device that reduces formation of bubbles during an edge material removal process.

### DETAILED DESCRIPTION

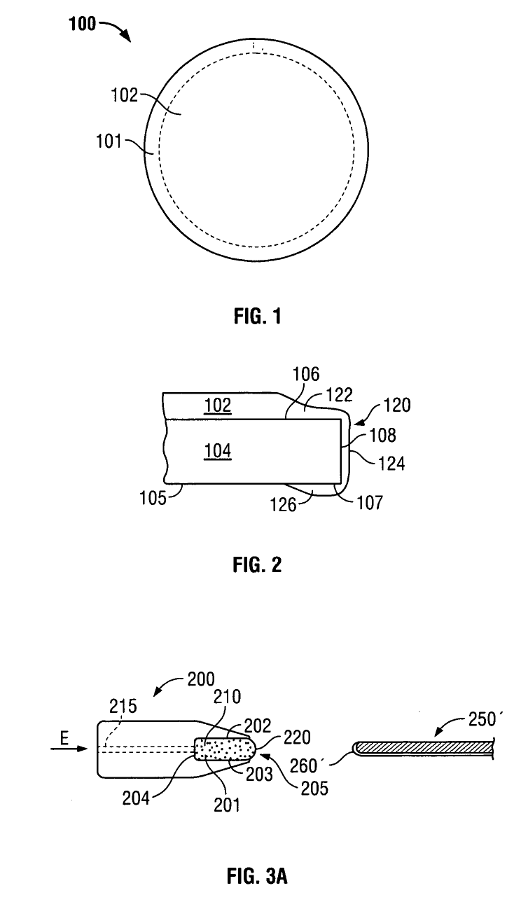

FIG. 1 is a top plane view of a plated work piece 100 such as a semiconductor wafer with an edge region 101 and surface region 102. After depositing the barrier and seed layers on this wafer, these conductive films often wrap around the bevel and reach the back side of the wafer. Since, during the electroplating, copper only deposits on the conductive regions that are coated with barrier or copper seed layer or with a barrier/seed composite layer, all conductive regions may then be coated with copper if they are exposed to the plating electrolyte during the plating process.

FIG. 2 shows an exemplary cross-section of a wafer near its edge after copper deposition. Barrier layer is not shown for simplicity. As can be seen from FIG. 2, the copper layer 102 may extend onto the side 108 and even the bottom surface 105 adjacent the edge 106, and thus forming an unwanted edge copper 120. The edge copper 120 may form around the circumference of the wafer 100, especially in plating approaches such as ECMD that deposits copper on full face of the wafer and also exposes the edge of the wafer to the plating solution. As exemplified in FIG. 2, the edge copper 120 may have an upper portion 122, a side portion 124 and a lower portion 126 over the top surface edge 106, side 108 and bottom surface edge 107, respectively. Although FIG. 2 schematically shows the thickness of the upper portion 122, side portion 124 and lower portion 126 of edge copper 120 to be thinner than the copper layer 102 on the surface, these portions may actually be thicker.

The edge copper portions 122-126 can be removed from the top surface edge 106, side 108 and bottom surface edge 107 by applying a copper etching solution through the process and apparatus of the present invention. Although, in this embodiment, the edge copper is exemplified using the upper, side and lower portions, it is understood that this is for the purpose of exemplifying the problem; consequently, the unwanted copper may just have the upper portion, or just the upper and side portions etc. Further, although the following process exemplifies a process for removing edge copper, the same principles can be used to remove unwanted portions of the other materials, such as photoresists or insulators, from an edge potion of a wafer.

It should be noted that in electrodeposition approaches where the regions 106, 108, and 107 are protected from the deposition solution by seals there may not be copper deposition on these regions during the electroplating step. However, even in the case where copper may not be deposited onto the regions 106, 108 and 107 of FIG. 2 during the plating step, there may be copper seed layer in those areas. Presence of such copper seed is typically not desirable and the seed needs to be removed after plating.

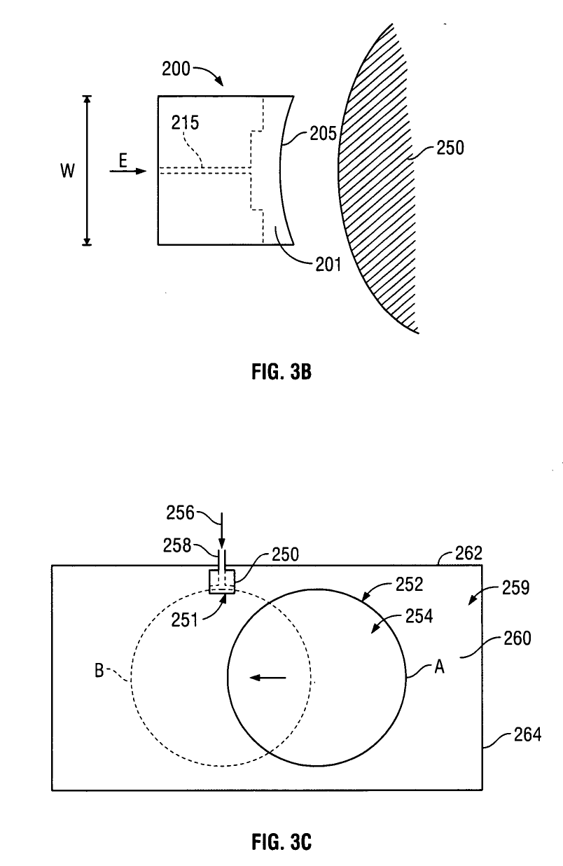

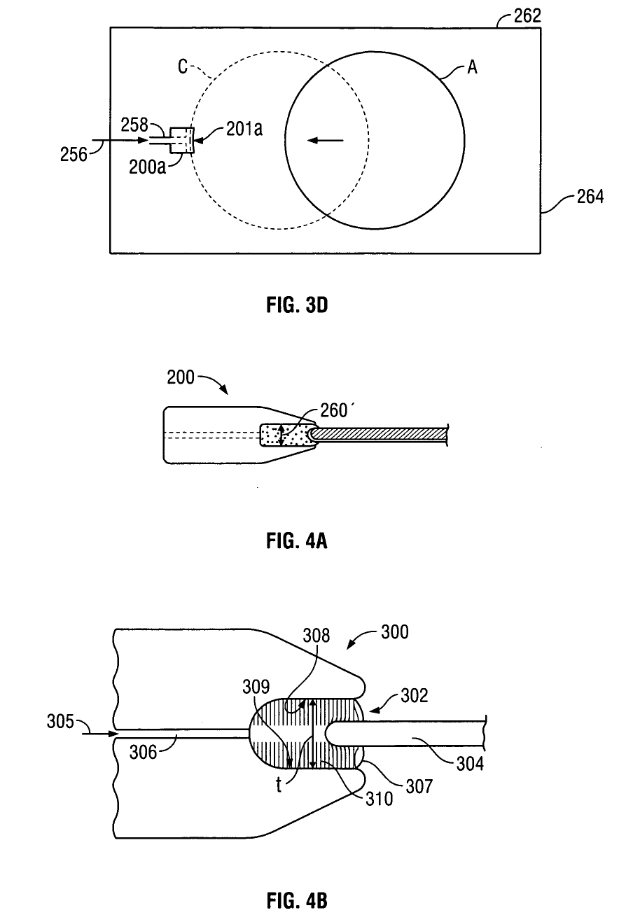

FIGS. 3A and 3B show the cross-sectional and top view schematics of the edge copper removal device 200 of the present invention. The device 200 has a slit or cavity 201 defined by an upper wall 202, a lower wall 203 and a back wall 204. The back wall 204 is preferably contoured to mateably receive an edge of the wafer. The front 205 is open and similarly contoured. An etching solution 210 is fed into the cavity 201 through a feed line 215 and fills up the cavity 201. The etching solution forms a bead 220 at the open front 205 of the device and may then slowly flow down the lower wall 203 leaving the cavity. The cavity 201 may take various shapes and forms as long as it forms and contains a thin sheet of the etching solution to be used to etch the conductor at the edge region of a wafer. As shown in FIG. 3B top view, the open front 205 of the device 200 is preferably curved with a curvature close or equal to the curvature of the wafer edge 250′, although a flat opening may also be used. An exemplary wafer 250′ with an edge copper layer 260′ with its upper, lower and side portions is shown in FIGS. 3A and 3B. Removal of the edge copper portions using the device and process of the present invention will now be described.

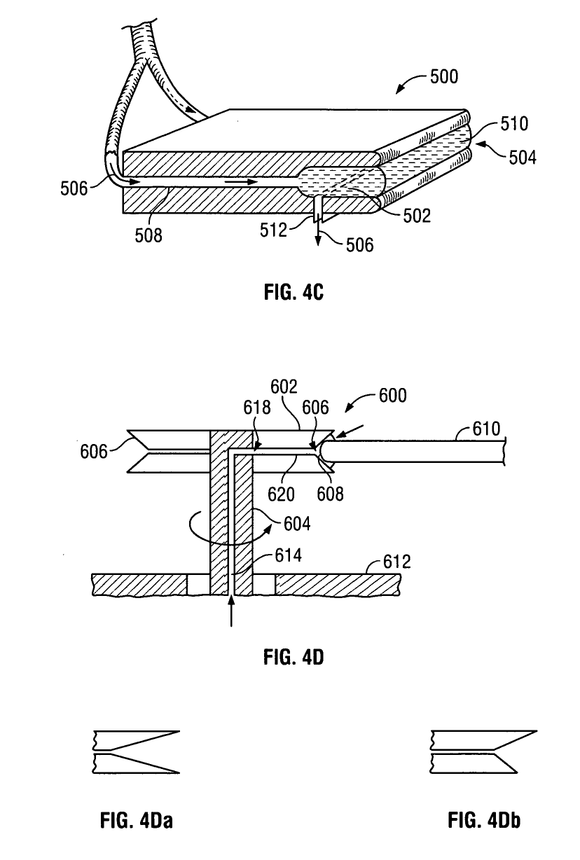

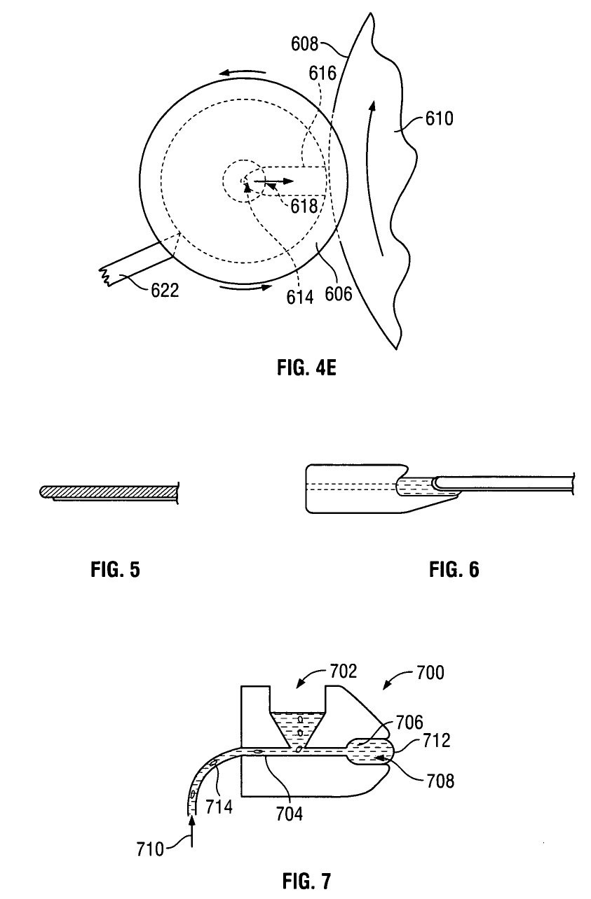

For edge copper removal, the wafer 250′ is first aligned with the cavity of the device 200 as shown in FIG. 3A. The wafer is then rotated and brought in close proximity of the open front 205 of the device 200 so that the etchant 210 in the cavity makes physical contact with the edge portion of the wafer and the surface tension of the etchant wraps the liquid around the edge portion (see FIG. 4A). By pushing the wafer more or less towards or into the cavity, this wrapped around region can be increased or decreased in a controllable fashion. As can be seen from FIG. 4A, unlike the traditional edge copper removal techniques that involve directing a stream of etchant precisely at a point at the edge of the wafer and spreading it by the action of the centrifugal force, the present invention forms a precise “pool” or sheet of the etchant and brings a portion of the wafer edge in contact with the etchant pool causing the etchant to wrap around the edge portion which includes the top, bottom and side portions of the edge copper film. This way the etching rate of the copper on the bevel does not become a sensitive function of the parameters such as the rpm of the wafer and the amount of the delivered etchant as it is in the case of prior art technique. The bevel of the wafer passes through the solution of the cavity of the device 200, and thus it is always immersed in the etchant pool until it exits the cavity. Therefore material removal is not expected to be very sensitive to rpm and the amount of flow of etchant into the cavity. As a result the edge copper is efficiently removed from the whole edge portion including the top, bottom and side as shown in FIG. 5. Obviously for the case of photoresist or other organic layer removal, the copper etchant would be replaced with another etchant that effectively removes that material.

The flow of the etchant into the device 200 needs to be adequate to keep a stable pool of etchant in the cavity. This flow is typically lower than the flow required by the nozzles of prior art technique that has to form a stable stream of etchant. For example, the flow required by the device 200 may be in the range of 0.1 ml/sec-5 ml/sec depending upon the size of the cavity and the device, although larger flows may be used as long as the etchant is not squirted towards the wafer front surface at high speed causing defects. Since prior art nozzles need to form a stable stream of etchant they require higher pressure etchant supply (e.g. 10-20 psi). The present device can operate with very low etchant supply pressures of for example 0.5-5 psi. The rotation of the wafer during etching may be in the range of 10-1500 rpm, preferably in the range of 200-1000 rpm depending on the size of the wafer. The cavity width 260′ shown in FIG. 4A should preferably be large enough for the wafer edge to slip in and freely rotate within, although it is possible that the cavity width is smaller than the thickness of the wafer and that the wafer edge never enters the cavity during edge copper removal. In this case wafer edge is brought close to the opening of the cavity and the edge copper removal is carried out when the bead 220 of the etchant makes physical contact with the edge portion and wets it. Although the preferred cavity width is in the range of 0.5-3 mm, wider or narrower slits may also be used. The width of the device 200 which is labeled as “W” in FIG. 3B may preferably be in the range of 2-5 cm, although narrower and larger devices may be employed. In fact W may be as large as the diameter of the wafer. It should be appreciated that the etch rate may be higher for larger W values since the residence time of each segment of the wafer edge portion in the etchant pool increases for larger W. The etchant may be brought into the cavity by various means through input holes that may be placed anywhere on the device. The etchant that can be used for copper removal may be a sulfuric acid and hydrogen peroxide mixture in water where the concentration of the acid and peroxide may be each in the range of 5-25%. Other etchant solutions may also be employed for copper or for other materials that needs to be removed from the edge of a workpiece.

Although a specific exemplary design of the edge copper removal device is described herein, it should be appreciated that the core of this invention is usage of any device that forms a stable and precise pool of an etchant, and immersing and rotating the edge portion of the wafer into this pool in a controlled manner to remove the edge copper. Although the preferred device design calls for the formation of a narrow cavity within which etchant flow may be laminar, other versions of the device may also be employed to carry out the process of the present invention. For example, the cavity of the device may be filled with a spongy material to regulate the flow and distribution of the etchant. In this case the wafer edge may or may not touch the spongy material.

FIGS. 3C and 3D show two possible device placement embodiments, in plan view, to perform edge material removal process by utilizing the edge material removal devices described in this application. These embodiments may be exemplified using a device 250, which is similar to the device 200 shown and described above embodiment. The device 250 has an opening 251 to place an edge portion 252 of a wafer 254. An etchant solution 256 is supplied to the opening 251 through the line 258. The device 250 is placed over a surface 259 of a process platform 260 where a wafer carrier (not shown) holding the wafer 254 may be used to lower the wafer for edge material removal. The platform may have a rectangular shape including a long and short sides 262 and 265. Although, for the sake of clarity, the wafer carrier is not included in the drawings, the wafer carrier holding the wafer 254 may move the wafer in a direction perpendicular to the surface 259 of the platform (z-direction), and also move the wafer laterally parallel to the surface of the platform.

As shown in FIG. 3C, in the first embodiment, the device 250 may be placed adjacent the long side of the platform. In one process sequence, the wafer 254 is first lowered along the z direction toward the surface 259 into a first position A over the platform and then moved in the x-direction laterally into a second position B so that the edge of the wafer engages with the opening 251. As the wafer is rotated an unwanted strip of material having a predetermined width at the edge 252 of the wafer is removed. Rinsing and cleaning may than be carried out using rinse nozzles (not shown) mounted on the surface 259. Wafer may then be raised and spin dried.

In a second embodiment shown in FIG. 3D, in one process sequence, the wafer 254 is first lowered along the z direction toward the surface 259 into first position A over the platform and then moved in the x-direction laterally into a second position C so that the edge of the wafer engages with the opening 251. As the wafer is rotated, an unwanted strip of material having a predetermined width at the edge 252 of the wafer is removed. However, in this embodiment, by moving the wafer in forward and backward along the x-direction, the width of the removed strip may be varied.

FIG. 4B shows an alternative embodiment for an edge copper removal device 300, having a particularly useful design. In this embodiment, opening 301 width “t” of a cavity 302 of the device is made large. Having a large opening width is attractive because it relaxes the tolerances needed to place a wafer 304 for edge material removal, especially in the z direction. The cavity 302 is fed by an etchant solution, 305 delivered through the line 306, and forms a bead 307 at the opening 301. It should be appreciated that with a wide opening of the cavity 302, the wafer 304 may be placed into the cavity 302 with less precision in z position and still avoid hitting the wafer to upper wall 308 or lower wall 309 of the cavity 302. Although the wide opening helps placement of the wafer 304, the wide opening, however, presents a problem in forming a well-behaved etchant bead at the opening. The etchant 305 may drip down before forming the etchant bead, although selecting the right material of construction for the device may improve this situation. In any case, in order to form a stable bead, a supplementary material 310 may be placed into the opening. In this embodiment, the supplementary material 310 may be comprised of soft bristles placed on the upper and lower cavity walls. The bristles 310 effectively reduce the width “t” and hold the etchant between them due to the surface tension. This way a stable bead may be formed even though the actual width “t” is large. Bristles may be made of any soft material that is compatible with the etchant. For example polypropylene would be good for sulfuric acid solutions.

FIG. 4C is a cross-sectional view of another edge bevel removal device 500 with cavity 502 and opening 504. Etchant solution 506 is delivered through the line 508 and forms a solution bead 510 at the opening 504. Stable bead formation may be enhanced by adding a draw-off port 512 to the line 508 or the cavity. Without the draw-off port the solution may drip down from the opening 504. This may disturb the shape of the bead. Draw off port removes the excess amount of the solution and releases the pressure within the cavity without solution dripping off the opening 504. The etchant solution running down the draw-off port regulates the etchant flow and assists the formation of a stable bead at the opening.

FIGS. 4D-4E show an alternative edge material removal device 600 which comprise an edge removal section 602 and a supply section 604. The edge removal section may be shaped as a wheel having a solution delivery opening 606 along its circumferential wall. The opening 606 may have a V-shape so that edge 608 of a wafer 610 can be inserted during the edge material removal process. As shown in cross-section in FIG. 4D, the supply section may be shaped as a shaft placed on a process platform 612 such as the one shown in FIGS. 3C-3D. The shaft 604 is movably connected to the center of the wheel. It is also possible that the shaft is stationary but the wheel is rotatable. As shown, in FIGS. 4D-4E, a solution supply line 614 runs through the shaft and, via a delivery hole 618, is connected to a radial channel 620 of the wheel. The radial channel 620 is radially connected to the opening 620. The wheel 602 is rotated along its rotational axis either by a drive mechanism (not shown) or rotated by the wafer 610 that is rotated by a wafer carrier (not shown) that holds the wafer. The delivery hole 618 is radially positioned against the edge of the wafer so that etchant solution is only delivered when the edge 608 is in the opening 606 but not when the edge is rotate away from the opening. A wiping device 622 may be used to wipe away the solution remaining in the opening 606 as the wheel rotates. It should be noted that the angles the sidewalls of the opening of the wheel may be changed to control the material removal from the edge region of the wafer. If the angle between the sidewalls is made larger, edge removal is reduced. If the angle is reduced and the V-shape is made taller, edge removal is increased. Some of the possible V-shaped openings are shown in FIGS. 4Da and 4Db.

An open cavity version of the device may also be employed as shown in FIG. 6. This design would be suitable especially for wafers with edge copper on the front and bevel but not so much on the back edge surface. In this case, the shallow tray formed by the open cavity of the device is filled to provide a pool of etchant. The wafer is rotated as its edge portion and front surface are brought in contact with the etchant. A sponge-like material may also be placed in the tray to retain the etchant. Wafer edge may or may not touch this sponge-like material.

Although the examples presented so far have shown a face-down wafer being processed (i.e. copper plated surface of the wafer facing down) the invention can also be used by flipping the wafer over into face-up orientation. The device design of FIG. 6 would especially be useful to remove copper from the back edge and bevel of a face-up wafer while minimizing removal from its front (upper) edge portion.

The above-described etching steps may be carried out in a specially designed, separate edge copper etching chamber or they may be carried out in the etching/cleaning section of a vertical chamber that also has a copper deposition section. Such designs are described in our previous patents and patent applications. After the etching process, the wafer is cleaned and dried. The cleaning step may involve rinsing of the whole wafer surface or rinsing of just the edge region through the use of another device similar to the one in FIG. 3A delivering not etchant but water to the edge portion of the wafer. Alternately the etchant delivery device may also be used for edge rinsing of the wafer by shutting off the etchant supply after the completion of edge copper removal and turning on a water supply tied to feed line 215, which then fills the cavity with water and rinses the edge of the wafer off acid etchant residues. As the wafer is rotated an unwanted strip of material having a predetermined width at the edge 252 of the wafer is removed.

FIG. 7 shows an alternative embodiment to prevent possible bubble problems in the edge material removal devices. Bubbles in the etchant solution may cause discontinuities in flow and pressure changes, which may negatively affect the removal process by causing splashes of the etchant and inconsistent edge of removal. In one exemplary embodiment, an edge material removal device 700 may be designed with an upper bleed opening 702 connected to a supply line 704 of the device. The device comprises cavity 706 having an opening 708 similar to the previous embodiments. The bleed opening 702 provides an area for the etchant solution to pool as bubbles bleed from the etchant solution. Accordingly, as the etchant solution 710 flows through line 704 and the bleed opening 702 into the cavity 706 to form a bead 712 at the opening 708, the bleed opening 702 pools the etchant solution and bleeds the bubbles 714 from etchant solution.

The material of construction for the edge material removal devices of the present invention must be selected carefully. The material of the cavity should be inert with respect to the etchant. For acidic etchants or photoresist etchants, stainless steel and inert polymeric materials would be appropriate. Wetting characteristics of the material of the cavity affect the type of bead formed at the opening. It is possible to form a convex or concave shape for the etchant bead by selecting a material that has a high contact angle or low contact angle with the etchant.

Although various preferred embodiments have been described in detail above, those skilled in the art will readily appreciate that many modifications of the exemplary embodiment are possible without materially departing from the novel teachings and advantages of this invention.

1. A method of removing a conductive material from an edge region of a workpiece comprising the steps:
supplying an etch solution to create an etchant bead at a contoured opening of an edge removal device;
contacting the edge region of the workpiece with the etchant bead;
establishing relative motion between the workpiece and the edge removal device to remove the conductive material from the edge region of the workpiece.

2. The method of claim 1, wherein the step of supplying the etch solution includes the step of maintaining the etchant bead at the opening of the edge removal device.

3. The method of claim 1, wherein the edge removal device includes a cavity having the opening and the step of contacting the etchant bead includes inserting the edge region of the workpiece into the cavity.

4. The method of claim 3, wherein the edge region includes a top area, a bottom area, and a side area of the workpiece and the step of contacting the etchant bead includes contacting the etch solution with the top area, the bottom area, and the side area of the workpiece.

5. The method of claim 4, wherein the cavity further includes an open area and the step of contacting the etchant bead includes contacting a pool of the etch solution with the bottom area and the side area of the workpiece.

6. The method of claim 4, wherein the cavity further includes an open area and the step of contacting the etchant bead includes contacting a pool of the etch solution with the top area and the side area of the workpiece.

7. The method of claim 3, wherein the cavity includes a spongy material.

8. The method of claim 7, wherein the step of contacting the etchant bead includes contacting the edge region of the workpiece with the spongy material.

9. The method of claim 3, wherein the cavity includes a large opening having supplementary material placed in the opening and the step of creating an etchant bead includes forming the etchant bead with the supplementary material.

10. The method of claim 8, wherein the supplementary material comprises soft bristles placed on an upper cavity wall and a lower cavity wall.

11. The method of claim 3, wherein the cavity includes a draw-off port and the step of supplying the etch solution includes flowing the etch solution out through the draw-off port.

12. The method of claim 3, wherein the cavity includes an upper bleed opening coupled to the cavity and further comprises the step of bleeding bubbles from a pool of the etch solution contained in the upper bleed opening.

13. The method of claim 4, wherein the opening includes a V-shaped opening and the step of maintaining the etchant bead includes maintaining an etchant bead at the V-shaped opening.

14. The method of claim 13, wherein the edge removal device includes an edge removal ring having the V-shaped opening and the step of establishing relative motion includes rotating the edge removal ring.

15. The method of claim 14 further comprising the step of varying the V-shaped opening to control an amount of the etchant bead in contact with the top area, the bottom area, and the side area of the workpiece.

16. The method of claim 14, wherein the V-shaped opening includes a spongy material.

17. The method of claim 16, wherein the step of contacting the etchant bead includes contacting the edge region of the workpiece with the spongy material.

18. The method of claim 14 further comprising the step of wiping the V-shaped opening with a wiping device.

19. An integrated circuit manufactured including the steps of claim 1.

20. An integrated circuit manufactured including the steps of claim 14.

21. An apparatus for removing a conductive material from an edge region of a workpiece using an etch solution, comprising:
a feed line configured to receive the etch solution;
a cavity having a contoured opening coupled to the feed line and configured to receive the etch solution and form an etchant bead at the cavity opening; and
a workpiece carrier configured to contact the edge region of the workpiece with the etchant bead to remove the conductive material.

22. The apparatus of claim 21, wherein the workpiece carrier is configured to rotate the workpiece.

23. The apparatus of claim 21, wherein the contoured opening of the cavity includes an edge contour substantially similar to the workpiece.

24. The apparatus of claim 21, wherein the workpiece carrier is configured to translate the workpiece with respect to the cavity.

25. The apparatus of claim 21, wherein:
the cavity includes an open area;
the edge region of the workpiece includes a top surface area, a bottom surface area, and a side area; and
the workpiece carrier is configured to contact a surface area and the side area of the workpiece with the etchant bead.

26. The apparatus of claim 21, wherein the cavity includes spongy material.

27. The apparatus of claim 21, wherein the cavity includes a large contoured opening having supplementary material in the large contoured opening.

28. The apparatus of claim 21 further comprising a bleed opening coupled to the feed line and the cavity configured to form a pool of the etch solution and bleed bubbles from the etch solution through the bleed opening.

29. The apparatus of claim 21 further comprising a wheel having a V-shaped circumferential wall fluidly coupled to the feed line and the cavity, the wheel configured to receive the etch solution and form an etchant bead at the V-shaped circumferential wall.

30. The apparatus of claim 29, wherein the V-shaped circumferential wall is configured to rotate.

31. The apparatus of claim 29, wherein the V-shaped circumferential wall is configurable to control an amount of the etchant bead in contact with the edge region of the workpiece.

32. The apparatus of claim 29 further comprising a wiping device coupled to the V-shaped circumferential wall configured to remove residual etch solution remaining in the V-shaped circumferential wall.
